(19) United States
(12) Patent Application Publication
(10) Pub. No.: US 2011/0120767 A1
(43) Pub. Date: May 26, 2011

(54) ANISOTROPIC ELECTRICALLY CONDUCTIVE FILM AND METHOD FOR MANUFACTURING CONNECTION ASSEMBLY USING THE SAME

(75) Inventors: Daisuke Sato, Tochigi (JP); Hiroki Ozeki, Tochigi (JP); Tomoyuki Ishimatsu, Tochigi (JP)

(73) Assignee: SONY CHEMICAL & INFORMATION DEVICE CORPORATION, Tokyo (JP)

(21) Appl. No.: 12/674,987

(22) PCT Filed: May 20, 2008
(86) PCT No.: PCT/JP2008/059187

§ 371 Date: Feb. 24, 2010

(30) Foreign Application Priority Data
Aug. 24, 2007 (JP) 2007-218863

(51) Int. Cl. H01B 1/12; H01R 4/04; H05K 13/00

(52) U.S. Cl. 174/84 R; 252/500; 156/297

(57) ABSTRACT

An anisotropic conductive film that may give rise to high connection reliability, and a method for manufacturing a connection assembly with the use of the anisotropic conductive film, are disclosed. An anisotropic conductive film (2) is composes of an insulating adhesive resin containing polybutadiene particles, a cationic polymerizable resin and a cationic curing agent, and conductive particles dispersed in the insulating adhesive resin, with the lowest melt viscosity of the anisotropic conductive film being 300 to 1000 Pa·s. This anisotropic conductive film is placed in contact with terminal electrodes of a glass substrate (1). A flexible printed circuit board (3) is placed on top of the anisotropic conductive film so that terminal electrodes of the flexible printed circuit board (3) are in contact with the anisotropic conductive film (2). A heating tool is thrust onto the flexible printed circuit board side for electrically interconnecting the terminal electrodes.

### TECHNICAL FIELD

This invention relates to an anisotropic electrically conductive film, in which there are contained electrically conductive particles, dispersed therein, and a method for manufacturing a connection assembly using the anisotropic electrically conductive film.

The present application claims priority rights based on the Japanese Patent Application No. 2007-218863 filed in Japan on Aug. 24, 2007. The total disclosure of the Patent Application of the senior filing date is to be incorporated herein by reference.

### BACKGROUND ART

To bond a glass substrate and a flexible printed circuit (FPC) board together, FOG (Film on Glass) bonding has so far been used (see Patent Publication 1 for instance). In this mounting method, a flexible printed circuit board is placed on a glass substrate, with an anisotropic conductive film in-between, so that connection terminals formed on the glass substrate face connection terminals formed on the flexible printed circuit board. The connection terminals are pressured to each other, as the anisotropic conductive film is heated and cured, using a heating tool, thereby interconnecting the connection terminals.
Patent Publication 1: Japanese Patent No. 3477367

### DISCLOSURE OF THE INVENTION

### Problem to be Solved by the Invention

However, the flexible printed circuit board has a coefficient of linear expansion greater than that of the glass substrate, and hence it is difficult to bonding the flexible printed circuit board and the glass substrate together to high mounting accuracy. For example, the coefficient of linear expansion of the polyimide resin, routinely used for the flexible printed circuit board, is 10 to 40×10⁻⁶/° C., which is higher than the coefficient of linear expansion of glass of approximately 8.5×10⁻⁶/° C. Viz., the very property of the flexible printed circuit board that it may be expanded with ease detracts from connection reliability.

More specifically, if, in thermal compression bonding, a heating head is contacted with and pressured against the flexible printed circuit board at a high speed, the curing reaction on the part of the anisotropic conductive film is initiated before sufficient extension of the interval between circuit patterns. Hence, the flexible printed circuit board and the anisotropic conductive film are bonded together as the interval between the circuit patterns of the flexible printed circuit board is not finely fit to the interval between the circuit patterns of the glass substrate. If conversely the heating head is contacted with and pressured against the flexible printed circuit board at a slower speed, curing occurs before the anisotropic conductive film becomes fluid. As a result, the flexible printed circuit board and the anisotropic conductive film are bonded together as the connection terminals are set apart from one another.

In addition, the bonding strength is deteriorated by the inner stress produced at a boundary between the anisotropic conductive film and the glass substrate or at a boundary between the anisotropic conductive film and the flexible printed circuit board during thermal compression bonding.

The present invention is proposed in consideration of the above described status of the related art. It is an object of the present invention to provide an anisotropic conductive film, capable of assuring high connection reliability, and a method for manufacturing a connection assembly that uses the anisotropic conductive film.

The present inventor conducted eager researches to solve the problem as above described and has found that high connection reliability may be achieved by adding polybutadiene particles as a stress relaxation agent and setting the lowest melt viscosity to 300 to 1000 Pa·s.

That is, an anisotropic conductive film according to the present invention is composed of an insulating adhesive resin containing polybutadiene particles, a cationic polymerizable resin and a cationic curing agent, and conductive particles dispersed in the insulating adhesive resin, with the lowest melt viscosity of the anisotropic conductive film being 300 to 1000 Pa·s.

A method for manufacturing a connection assembly according to the present invention is such a method in which a glass substrate having a plurality of terminal electrodes formed thereon at a predetermined interval, and a flexible printed circuit board having a plurality of terminal electrodes formed thereon at a predetermined interval narrower than the interval of the terminal electrodes of the glass substrate, are connected to each other by an anisotropic conductive film. The method includes the step of placing the anisotropic conductive film on the terminal electrodes of the glass substrate, in which the anisotropic conductive film is composes of an insulating adhesive resin containing polybutadiene particles, a cationic polymerizable resin and a cationic curing agent, and conductive particles dispersed in the insulating adhesive resin, with the lowest melt viscosity of the anisotropic conductive film being 300 to 1000 Pa·s. The method also includes the step of placing the terminal electrodes of the flexible printed circuit board on the anisotropic conductive film, and pressuring the terminal electrodes of the flexible printed circuit board and the anisotropic conductive film from the flexible printed circuit board side, by using a heating tool, for electrically interconnecting the terminal electrodes of the flexible printed circuit board and the terminal electrodes of the glass substrate.

A connection assembly according to the present invention is such a one in which terminal electrodes of a glass substrate and terminal electrodes of a flexible printed circuit board are bonded together by an anisotropic conductive film, placed in-between, with the lowest meting viscosity of the anisotropic conductive film being 300 to 1000 Pa·s.

### BRIEF DESCRIPTION OF THE DRAWINGS

FIGS. 1A and 1B are plan views for illustrating a method for bonding a flexible printed circuit board and a glass substrate to each other according to an embodiment of the present invention.

### PREFERRED EMBODIMENT OF THE INVENTION

An embodiment of the present invention will now be described with reference to the drawing.

An anisotropic conductive film, shown as a concrete example of the present invention, is an insulating adhesive film in which there are dispersed electrically conductive particles.

As the electrically conductive particles, particles of metals, such as nickel, gold or copper, or gold-plated resin particles, may be used. It is also possible to use gold-plated resin particles having insulation coatings as the outermost layers. The average particle size of the conductive particles is preferably 1 to 20 μm from the perspective of conduction reliability. The amount of dispersion of the conductive particles in the insulating adhesive resin is preferably 2 to 50 wt % from the perspective of conduction reliability and insulation reliability.

The insulating adhesive resin may be obtained by dissolving a stress relaxation agent, a cationic polymerizable resin and a cationic curing agent in a suitable solvent.

As the stress relaxation agent, particles of polybutadiene, an elastomeric material, are used. Butadiene rubber (BR), formed of polybutadiene, is higher in its rebound resilience than acrylic rubber (ACR) or nitrile rubber (NBR), and hence is possible to absorb the inner stress more effectively. Moreover, butadiene rubber is not prone to curing defects, thus assuring high connection reliability.

The modulus of elasticity of the polybutadiene particles is preferably smaller than that of the as-cured insulating adhesive resin. More specifically, the modulus of elasticity in a range from 1×10⁸ to 1×10¹⁰ dyn/cm² is preferred. If the modulus of elasticity is smaller than 1×10⁸ dyn/cm², the force of retention is undesirably lowered. If conversely the modulus of elasticity is larger than 1×10¹⁰ dyn/cm², undesirably it becomes not possible to reduce the inner stress of the insulating adhesive resin to a sufficiently small value.

Additionally, the exothermic peak temperature of the polybutadiene particles, as measured by DSC (Differential Scanning Calorimeter), is preferably 80 to 120° C. If the exothermic peak temperature of the polybutadiene particles is smaller than 80° C., the product life of the anisotropic conductive film is undesirably shortened. If conversely the exothermic peak temperature is higher than 120° C., curing defects are undesirably produced.

On the other hand, the average particle size of the polybutadiene particles is preferably smaller than that of the conductive particles in order to maintain sufficient electrical connection between the conductive particles and electrodes for connection. Specifically, the average particle size of the polybutadiene particles in a range from 0.01 to 0.5 μm is preferred. If the average particle size of the polybutadiene particles is smaller than 0.01 μm, the stress undesirably cannot sufficiently be absorbed, whereas, if the average particle size is larger than 0.5 μm, the electrical connection between the conductive particles and the connection electrodes undesirably tends to be lowered.

Preferably, the polybutadiene particles are contained in an amount of 5 to 35 parts by weight to 70 parts by weight of the cationic polymerizable resin. If the mixing ratio is less than 5 parts by weight, it is not possible to sufficiently reduce the inner stress generated in a binder. If conversely the mixing ratio is larger than 35 parts by weight, it becomes difficult to form a film and also the resistance to heat is undesirably lowered.

As the cationic polymerizable resins, mono-functional epoxy compounds, such as ethylene oxide, propylene oxide, butylene oxide, styrene oxide, phenyl glycidyl ether or butyl glycidyl ether, may be used. It is also possible to use heterocyclic epoxy resins, such as bisphenol A epoxy resins, bisphenol F epoxy resins, phenol novolac epoxy resins, alicyclic epoxy resins, triglycidyl isocyanate or hydantoin epoxy. It is also possible to use aliphatic epoxy resins, such as hydrogenated bisphenol A epoxy resins, propylene glycol diglycidyl ether or pentaerythrytol-polyglycidyl ether. It is also possible to use epoxy resins obtainable on reactions of aromatic, aliphatic or alicyclic carboxylic acids with epichlorohydrin. It is also possible to use spiro containing epoxy resins. It is also possible to use glycidyl ether epoxy resins which are reaction products of o-allyl-phenol novolac compounds with epichlorohydrin. It is also possible to use glycidyl ether epoxy resins which are reaction products of diallyl bisphenol compounds containing allyl groups at ortho positions of respective hydroxyl groups of bisphenol A and epichlorohydrin. It is also possible to use diglycidyl ether epoxy resins of Shiff base compounds, stilbene compounds and azobenzene compounds. It is further possible to use fluorine-containing alicyclic or aromatic ring type epoxy resins, such as reaction products of (1,1,1,3,3,3-hexafluoro-2-hydroxyisopropyl) cyclohexane and epichlorohydrin. Of these, epoxy resins such as bisphenol A epoxy resins, bisphenol F epoxy resins, phenoxy resins, naphthalene epoxy resins and novolac epoxy resins, are preferably used either singly or in combination.

Preferably, the cationic polymerizable resins are mixtures of phenoxy resins and epoxy resins. The molecular weight of the phenoxy resin is preferably 20000 to 60000 from the perspective of film forming. If the phenoxy resin has the molecular weight less than 20000, it is increased in fluidity to deteriorate the film forming property. If the molecular weight is greater than 60000, the phenoxy resin is lowered in fluidity.

Preferably, the epoxy resin contains at least one of the bisphenol F resin and the bisphenol A resin. This may enable a film of optimum fluidity to be formed.

In the cationic curing agent, cations may cause ring-opening of the epoxy groups at the terminal end of the epoxy resin to allow for self cross-linking in the epoxy resin. The cationic curing agent may be enumerated by onium salts, such as aromatic sulfonium salts, aromatic diazonium salts, iodonium salts, phosphonium salts and selenonium salts. In particular, the aromatic sulfonium salts are suited as cationic curing agents because they are high in reactivity at lower temperatures and have a longer pot life.

As a solvent, toluene and ethyl acetate, for example, may be used.

The method for manufacturing an anisotropic conductive film will now be described. Initially, a selected cationic resin is dissolved in a solvent. Predetermined amounts of polybutadiene particles and a cationic curing agent are dissolved in the resulting solution and mixed together. Conductive particles are added and dispersed to the resulting solution containing the polybutadiene particles to prepare a binder. This binder is coated on, for example, a release film of polyester, and dried in situ. After drying, a cover film is laminated on the so coated binder to yield an anisotropic conductive film.

Preferably, this anisotropic conductive film has a lowest melt viscosity in a range from 300 to 1000 Pa·s. If the lowest melt viscosity is not higher than 300 Pa·s, the binder, as the insulating adhesive resin in the anisotropic electrically conductive film, becomes fluidized and may not be anchored at a connecting portion, thus deteriorating the connection strength. On the other hand, if the lowest melt viscosity is not lower than 1000 Pa·s, the binder is deteriorated in fluidity. Also the connection thickness becomes larger than the diameter of the conductive particle to worsen the connection reliability. Meanwhile, the lowest melt viscosity is preferably reached at a temperature between 90° C. and 110° C. If the reached temperature is lower than 90° C., the fluidity becomes excessive, whereas, if the reached temperature is higher than 110° C., fluidity is not sufficient.

With the use of this anisotropic conductive film, a glass substrate and a flexible board may be interconnected with high reliability under a thermal compression bonding condition of 150 to 200° C. and 4 to 6 seconds.

A method for manufacturing a connection assembly will now be described. Meanwhile, the connection assembly is composed of a glass substrate and a flexible substrate interconnected by the above mentioned anisotropic conductive film.

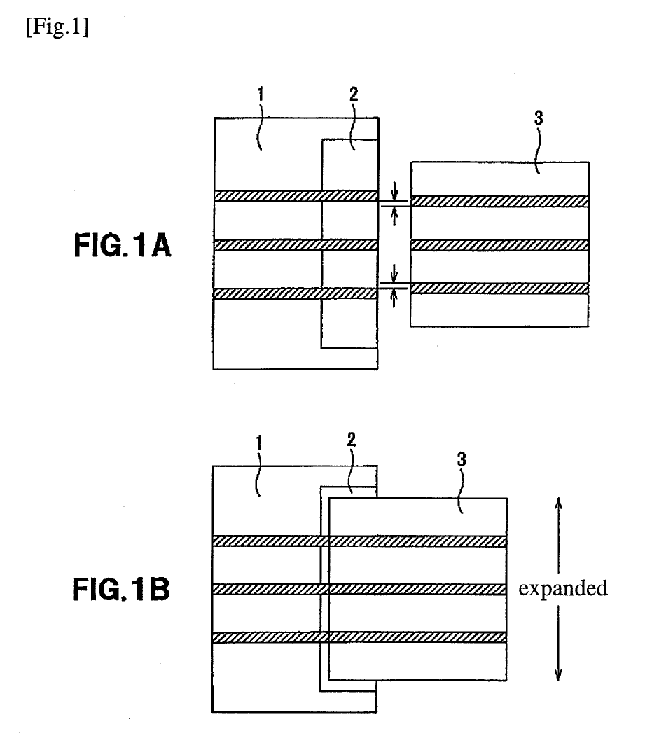

FIGS. 1A and 1B are top plan views for illustrating the method for bonding a flexible printed circuit board and a glass substrate in an embodiment of the present invention. As shown in FIG. 1A, a plurality of terminal electrodes are formed at predetermined intervals from one another on a glass substrate 1. Also, a plurality of terminal electrodes are formed on a flexible printed circuit board 3 at predetermined intervals from one another, these intervals are set so as to be narrower than the intervals of the terminal electrodes on the glass substrate 1. An anisotropic conductive film 2, described above, is placed on top of the terminal electrodes of the glass substrate 1. The terminal electrodes of the flexible printed circuit board 3 are placed on the anisotropic conductive film 2. A heating tool, not shown, is pressured onto the resulting assembly from the side the flexible printed circuit board 3 for electrically interconnecting the terminal electrodes. At this time, the flexible printed circuit board 3 is thermally expanded such that the interval between the terminal electrodes of the flexible printed circuit board 3 becomes approximately equal to that between the terminal electrodes of the glass substrate 1, as shown in FIG. 1B.

It is preferred that, in the present embodiment, the thrust speed of the heating tool is set to 1 to 50 mm/sec and that the electrodes facing each other are electrically connected together in the pressuring direction under the connection conditions of 150 to 200° C. and 4 to 6 sec. If the thrust speed is smaller than 1 mm/sec, the binder may not be removed in its entirety to give rise to conduction failure.

With the use of the anisotropic conductive film of the lowest melt viscosity of 300 to 1000 Pa·s, the fluidity during thermal compression bonding is optimized. Moreover, the inner stress produced at the connection boundary portion may be absorbed by the polybutadiene particles added in the anisotropic conductive film, thus enabling producing a connection assembly of high connection reliability.

### EXAMPLE

Several Examples of the present invention will now be described in detail in connection with Comparative Examples. First, samples of anisotropic conductive films of Examples 1 to 7 and Comparative Examples 1 to 5 were prepared as shown in Table 1.

TABLE 1

| | | Film forming components | | | | | | | | |
|---|---|---|---|---|---|---|---|---|---|---|
| | | (parts by weight) | | | Epoxy | | | | | |
| | | | | Mw: | components | | | | | |
| | | Mw: 60000 | Mw: 30000 | 20000 | (parts by | | | | | |
| | Latent | Bis- | Bis- | Bis-F | weight) | | | | | |
| | curing | A/Bis-F | A/Bis-F | mixed | Liquid | Liquid | Stress relaxation agents | | | Conductive |
| | agent | mixed high | mixed high | high | Bis-A | Bis-F | (parts by weight) | | | particles |
| | (parts by | molecular | molecular | molecular | epoxy | epoxy | Butadiene | Acrylic | Nitrile | (parts by |
| | weight) | material | material | material | resin | resin | rubber | rubber | rubber | weight) |
| Ex. 1 | 5 | | 40 | | 20 | 10 | 5 | | | 5 |
| Ex. 2 | 5 | | 40 | | 20 | 10 | 10 | | | 5 |
| Ex. 3 | 5 | | 40 | | 20 | 10 | 20 | | | 5 |
| Ex. 4 | 5 | | 20 | 20 | 20 | 10 | 20 | | | 5 |
| Ex. 5 | 8 | | 20 | 20 | 20 | 10 | 20 | | | 5 |
| Ex. 6 | 5 | 30 | | 10 | 20 | 10 | 20 | | | 5 |
| Ex. 7 | 5 | | 40 | | 20 | 10 | 35 | | | 5 |
| Comp. Ex. 1 | 5 | 40 | | | 20 | 10 | | | | 5 |
| Comp. Ex. 2 | 5 | | | 40 | 20 | 10 | 20 | | | 5 |
| Comp. Ex. 3 | 2 | | 20 | 20 | 20 | 10 | 20 | | | 5 |
| Comp. Ex. 4 | 5 | | 40 | | 20 | 10 | | 20 | | 5 |
| Comp. Ex. 5 | 5 | | 40 | | 20 | 10 | | | 20 | 5 |

### Example 1

As a cationic polymerizable resin, a mixture of 40 parts by weight of a Bis-A/Bis-F mixed type phenoxy resin with an average molecular weight of 30000 (manufactured by Japan Epoxy Resins Co., Ltd. under the trade name of jER-4210), 20 parts by weight of a liquid Bis-A epoxy resin of an equivalent of 190 (manufactured by Japan Epoxy Resins Co., Ltd. under the trade name of YL980), and 10 parts by weight of a liquid Bis-F epoxy resin of an equivalent of 160 (manufactured by Japan Epoxy Resins Co., Ltd. under the trade name of jER806), were used. As a stress relaxation agent, 5 parts by weight of butadiene rubber (BR) particles with an average particle size of 0.5 μm formed of polybutadiene (manufactured by Resinous Kasei Co., Ltd. under the trade name of RKB) were used. As a latent curing agent, 5 parts by weight of sulfonium base cationic curing agent (manufactured by Sanshin Chemical Industry Co., Ltd. under the trade name of SI-60L) were used. The cationic polymerizable resin, the stress relaxation agent and the latent curing agent were dissolved in a solvent toluene to prepare an insulating adhesive resin solution.

To 80 parts by weight of this insulating adhesive resin solution, 5 parts by weight of nickel-gold plated benzoguanamine particles with an average particle size of 0.5 μm were added as conductive particles to provide a binder.

This binder was coated on a release PET film to a dry thickness of 25 μm to provide an anisotropic conductive film. This anisotropic conductive film was cut into slits, each 2 mm in width, to provide samples of Example 1.

### Example 2

A sample of an anisotropic conductive film was prepared in the same way as in Example 1 except preparing a binder solution with the butadiene rubber particles of 10 parts by weight.

### Example 3

A sample of an anisotropic conductive film was prepared in the same way as in Example 1 except preparing a binder solution the butadiene rubber particles of 20 parts by weight.

### Example 4

A sample of an anisotropic conductive film was prepared in the same way as in Example 3 except preparing a binder solution with the use of 20 parts by weight of a Bis-A/Bis-F mixed type phenoxy resin with an average molecular weight of 30000 (manufactured by Japan Epoxy Resins Co., Ltd. under the trade name of jER-4210), and 20 parts by weight of a liquid Bis-F phenoxy resin (manufactured by Japan Epoxy Resins Co., Ltd. under the trade name of jER-4007P).

### Example 5

A sample of an anisotropic conductive film was prepared in the same way as in Example 4 except preparing a binder solution with the use of 8 parts by weight of the sulfonium base cationic curing agent (manufactured by Sanshin Chemical Industry Co., Ltd. under the trade name of SI-60L).

### Example 6

A sample of an anisotropic conductive film was prepared in the same way as in Example 4 except preparing a binder solution with the use of 30 parts by weight of Bis-A/Bis F mixed type phenoxy resin with an average molecular weight of 60000 (manufactured by Tohto Kasei Co., Ltd. under the trade name of YP-50), and 10 parts by weight of Bis-F phenoxy resin with an average molecular weight of 20000 (manufactured by Japan Epoxy Resin Co., Ltd. under the trade name of jER-4007P).

### Example 7

A sample of an anisotropic conductive film was prepared in the same way as in Example 1 except preparing a binder solution with the butadiene rubber particles of 35 parts by weight.

### Comparative Example 1

A sample of an anisotropic conductive film was prepared in the same way as in Example 1 except preparing a binder solution with the Bis-A/Bis-F mixed type phenoxy resin with the average molecular weight 60000 (manufactured by Tohto Kasei Co., Ltd. under the trade name of YP-50) of 40 parts by weight, and without adding the stress relaxation agent.

### Comparative Example 2

A sample of an anisotropic conductive film was prepared in the same way as in Example 1 except setting the amount of the Bis-F phenoxy resin with an average molecular weight 20000 (manufactured by Japan Epoxy Resins Co., Ltd. under the trade name of jER-4007P) to 40 parts by weight to prepare a binder solution.

### Comparative Example 3

A sample of an anisotropic conductive film was prepared in the same way as in Example 4 except setting the amount of the sulfonium base cationic curing agent (manufactured by Sanshin Kagaku Industry Co., Ltd. under the trade name of SI-60L) to 2 parts by weight to prepare a binder solution.

### Comparative Example 4

A sample of an anisotropic conductive film was prepared in the same way as in Example 1 except setting the amount of the acrylic rubber with an average particle size of 0.5 μm (manufactured by Nagase ChemteX Corporation under the trade name of SG600LB) to 20 parts by weight to prepare a binder solution.

### Comparative Example 5

A sample of an anisotropic conductive film was prepared in the same way as in Example 1 except setting the amount of the nitrile rubber (NBR) particles with an average particle size of 0.5 μm (manufactured by Zeon Corporation under the trade name of DN009) to 20 parts by weight to prepare a binder solution.

### (Results of Measurement)

Table 2 shows the results of measurement of the lowest melt viscosity of the above samples, the temperature when the lowest melt viscosity was reached and the peak temperature at the DSC (Differential Scanning Calorimeter). Regarding the lowest melt viscosity and the temperature when the lowest melt viscosity was reached, the melt viscosity was measured as a preset amount of the sample was loaded in a rotating viscometer and the temperature was raised at a preset rise rate. The peak DSC temperature was measured on a predetermined weighed out amount of the sample, by measurement with the DSC (Differential Scanning Calorimeter), with the temperature rise rate of 10° C./min.

TABLE 2

| | Lowest melt | Temperature (° C.) at | Peak |
|---|---|---|---|
| | viscosity | which the lowest | temperature |
| Samples | (Pa · s) | temperature was reached | of DSC (° C.) |
| Ex. 1 | 700 | 100 | 115 |
| Ex. 2 | 700 | 100 | 115 |
| Ex. 3 | 700 | 100 | 115 |
| Ex. 4 | 300 | 100 | 115 |
| Ex. 5 | 350 | 97 | 114 |
| Ex. 6 | 1000 | 100 | 115 |
| Ex. 7 | 800 | 100 | 115 |
| Comp. Ex. 1 | 1100 | 100 | 115 |
| Comp. Ex. 2 | 90 | 100 | 115 |
| Comp. Ex. 3 | 200 | 107 | 121 |
| Comp. Ex. 4 | 800 | 100 | 115 |
| Comp. Ex. 5 | — | — | — |

### (Results of Evaluation)

The above samples were placed on terminal electrodes of the glass substrate. On those samples, terminal electrodes of a flexible printed circuit board (two-layers; 38 μm thick; copper circuit 8 μm) were placed. The resulting product was pressured by a heating tool from the flexible printed circuit board side to pressure bond the flexible printed circuit board and the glass substrate together. The resistance to conduction and the bond strength were evaluated in connection with the influence of the thrust speed of the heating tool. The thermal pressuring conditions at this time were 170° C., 3.5 MPa and 4 sec.

Table 3 below shows the results of evaluation of the resistance to conduction and the bond strength in connection with variable thrust speeds of the heating tool. The resistance to conduction was measured on the resistance across the terminal electrodes of the two substrates thermally pressure bonded to each other. The bond strength measured on the force of adhesion when the flexible printed circuit board was released in a perpendicular direction from the glass plate thermally compression bonded to the flexible printed circuit board.

Table 4 below shows the results of evaluation of connection reliability. To evaluate the connection reliability, the connection assembly, obtained under the pressure bonding conditions of 170° C., 3.5 MPa and 4 sec and the thrust speed of the heating tool of 30 mm/sec, was processed with ageing under conditions in a range from the temperature of 85° C. and relative humidity of 85% to the temperature of 45° C. and relative humidity of 90% for 1000 hours. Then the resistance to conduction and the bond strength of the processed connection assembly were measured for evaluation.

TABLE 3

| | Resistance to conduction (Ω) | | | | | Bond strength (N/cm) | | | | |
|---|---|---|---|---|---|---|---|---|---|---|
| | 50 | | | | | | | | | 0.1 |
| Samples | mm/sec | 30 mm/sec | 10 mm/sec | 1.0 mm/sec | 0.1 mm/sec | 50 mm/sec | 30 mm/sec | 10 mm/sec | 1.0 mm/sec | mm/sec |
| Ex. 1 | 1.1 | 1.1 | 1.1 | 1.2 | 20 | 7.0 | 6.7 | 7 | 6.5 | 10 |
| Ex. 2 | 1.1 | 1.1 | 1.1 | 1.2 | 20 | 7.0 | 6.5 | 6.8 | 6.4 | 10 |
| Ex. 3 | 1.1 | 1.1 | 1.1 | 1.2 | 20 | 7.8 | 8.2 | 8.0 | 7.9 | 10 |
| Ex. 4 | 1.2 | 1.1 | 1.3 | 1.2 | 19 | 8.2 | 8.1 | 8.2 | 7.8 | 10 |
| Ex. 5 | 1.2 | 1.1 | 1.3 | 1.2 | 19 | 7.9 | 8.0 | 8.1 | 8.1 | 10 |
| Ex. 6 | 1.2 | 1.1 | 1.2 | 1.2 | 20 | 8.0 | 8.1 | 8.1 | 8.2 | 10 |
| Ex. 7 | 1.2 | 1.1 | 1.3 | 1.2 | 20 | 8.5 | 8.2 | 8.1 | 8.0 | 10 |
| Comp. Ex. 1 | 1.1 | 1.2 | 19 | 18 | 20 | 3 or less | 3 or less | 3 or less | 3 or less | 3 or less |
| Comp. Ex. 2 | 1.2 | 1.2 | 1.2 | 1.2 | 17 | 8.1 | 8.3 | 8.2 | 8.5 | 10 |
| Comp. Ex. 3 | 1.2 | 1.1 | 1.2 | 1.2 | 1.4 | 3 or less | 3 or less | 3 or less | 3 or less | 3 or less |
| Comp. Ex. 4 | 1.2 | 1.1 | 1.3 | 1.2 | 17 | 5.4 | 5.0 | 4.8 | 5.1 | 10 |
| Comp. Ex. 5 | 19 | 18 | 20 | 20 | 20 | 3 or less | 3 or less | 3 or less | 3 or less | 3 or less |

TABLE 4

| | Resistance to | Bond strength |
|---|---|---|
| Samples | conduction (Ω) | (N/cm) |
| Ex. 1 | 3.3 | 5 |
| Ex. 2 | 3.2 | 5 |
| Ex. 3 | 3.3 | 5 |
| Ex. 4 | 3.5 | 5 |
| Ex. 5 | 3.2 | 5 |
| Ex. 6 | 3.2 | 5 |
| Ex. 7 | 5.2 | 5 |
| Comp. Ex. 1 | 3.8 | 3 or less |
| Comp. Ex. 2 | 30 | 5 |
| Comp. Ex. 3 | 50 | 3 or less |
| Comp. Ex. 4 | 3.5 | 3 or less |
| Comp. Ex. 5 | 50 | 3 or less |

### (Extension/Contraction of Flexible Substrate)

Table 5 below shows the rate of extension/contraction of the flexible printed circuit board with respect to variable thrust speeds of the heating tool. Here, a flexible printed circuit board (manufactured by Du Pont-TORAY Co., Ltd. under the trade name of Capton EN) and a glass substrate (manufactured by Corning under the trade name of Corning 1737F) were bonded together by the samples of Examples 3 and 4. The rate of extension/contraction of the resulting flexible printed circuit board was then measured. The rate of extension/contraction of the flexible printed circuit board was calculated from the lengths of the flexible printed circuit boards measured before and after the thermal compression bonding by a two-dimensional length measurement device. Meanwhile, the thermal expansion coefficients of the flexible printed circuit board and the glass substrate were 16×10⁻⁶/° C. and 3.7×10⁻⁶/° C., respectively.

TABLE 5

| | Thrust speeds (mm/sec) | | |
|---|---|---|---|
| Samples | 1 | 10 | 30 |
| Ex. 3 | 0.19 | 0.14 | 0.09 |
| Ex. 4 | 0.20 | 0.15 | 0.10 |

It is seen from the above results that the fluidity of the anisotropic conductive film, having the lowest melt viscosity of 300 to 1000 Pa·s, becomes optimum under the thrust speed of the heating tool of 1 to 50 mm/sec and under the thermal compression bonding conditions of 150 to 200° C. and 4 to 6 sec. It is also seen that, since polybutadiene particles are contained in the anisotropic conductive film, the inner stress is absorbed so that high bond strength may be displayed.

For example, the connection assembly obtained by using the samples of Examples 1 to 7 showed high resistance to conduction and high bond strength with 170° C., 3.5 MPa and 4 sec and with a thrust speed ranging from 1 to 50 mm/sec of the heating tool.

Conversely, with the samples of Comparative Examples 1 to 5, in which the lowest melt viscosity is not optimum, no result testifying to high connection reliability could be obtained.

1. An anisotropic conductive film comprised of an insulating adhesive resin containing polybutadiene particles, a cationic polymerizable resin and a cationic curing agent, and conductive particles dispersed in said insulating adhesive resin, with the lowest melt viscosity of said anisotropic conductive film being 300 to 1000 Pa·s.

2. (canceled)

3. The anisotropic conductive film according to claim 1, wherein said polybutadiene particles are contained in an amount of 5 to 35 parts by weight to 70 parts by weight of said cationic polymerizable resin.

4. The anisotropic conductive film according to claim 1, wherein the modulus of elasticity of said polybutadiene particles ranges from 1×10⁸ to 1×10¹⁰ dyn/cm².

5. The anisotropic conductive film according to claim 1, wherein the average particle size of said polybutadiene particles ranges from 0.01 to 0.5 μm.

6. The anisotropic conductive film according to claim 1, wherein said cationic polymerizable resin is a mixture of a phenoxy resin and an epoxy resin and wherein the molecular weight of said phenoxy resin is 20000 to 60000.

7. The anisotropic conductive film according to claim 6, wherein said epoxy polymerizable resin contains at least one out of bisphenol F and bisphenol A.

8. The anisotropic conductive film according to claim 1, wherein the exothermic peak temperature in a differential scanning calorimeter is 110 to 120° C. for the temperature rise rate of 10° C./min.

9. A method for manufacturing a connection assembly in which a glass substrate having a plurality of terminal electrodes formed thereon at a predetermined interval and a flexible printed circuit board having a plurality of terminal electrodes formed thereon at a predetermined interval narrower than said interval of said terminal electrodes of said glass substrate are connected to each other by an anisotropic conductive film; said method comprising:
placing said anisotropic conductive film on said terminal electrodes of said glass substrate; said anisotropic conductive film being comprised of an insulating adhesive resin containing polybutadiene particles, a cationic polymerizable resin and a cationic curing agent, and conductive particles dispersed in said insulating adhesive resin, with the lowest melt viscosity of said anisotropic conductive film being 300 to 1000 Pa·s;
placing said flexible printed circuit board on said anisotropic conductive film so that said terminal electrodes of said flexible printed circuit board contact said anisotropic conductive film; and
pressuring said terminal electrodes of said flexible printed circuit board and said anisotropic conductive film from said flexible printed circuit board side by using a heating tool for electrically interconnecting said terminal electrodes of said flexible printed circuit board and said terminal electrodes of said glass substrate.

10. The method for manufacturing a connection assembly according to claim 9, wherein said heating tool is thrust at 150 to 200° C. for 4 to 6 seconds at a thrust speed of 1 to 50 mm/sec.

11. A connection assembly in which terminal electrodes of a glass substrate and terminal electrodes of a flexible printed circuit board are bounded together by an anisotropic conductive film, placed in-between; wherein the lowest melt viscosity of said anisotropic conductive film is 300 to 1000 Pa·s.

12. (canceled)

13. The anisotropic conductive film according to claim 1, wherein said lowest melt viscosity is reached at 90 to 100° C.

14. The anisotropic conductive film according to claim 3, wherein the modulus of elasticity of said polybutadiene particles ranges from 1×10⁸ to 1×10¹⁰ dyn/cm².

15. The anisotropic conductive film according to claim 13, wherein the modulus of elasticity of said polybutadiene particles ranges from 1×10⁸ to 1×10¹⁰ dyn/cm².

16. The anisotropic conductive film according to claim 13, wherein said cationic polymerizable resin is a mixture of a phenoxy resin and an epoxy resin and wherein the molecular weight of said phenoxy resin is 20000 to 60000.

17. The anisotropic conductive film according to claim 3, wherein said cationic polymerizable resin is a mixture of a phenoxy resin and an epoxy resin and wherein the molecular weight of said phenoxy resin is 20000 to 60000.

18. The anisotropic conductive film according to claim 4, wherein said cationic polymerizable resin is a mixture of a phenoxy resin and an epoxy resin and wherein the molecular weight of said phenoxy resin is 20000 to 60000.

19. The anisotropic conductive film according to claim 5, wherein said cationic polymerizable resin is a mixture of a phenoxy resin and an epoxy resin and wherein the molecular weight of said phenoxy resin is 20000 to 60000.

20. The anisotropic conductive film according to claim 13, wherein the exothermic peak temperature in a differential scanning calorimeter is 110 to 120° C. for the temperature rise rate of 10° C./min.

21. The anisotropic conductive film according to claim 3, wherein the exothermic peak temperature in a differential scanning calorimeter is 110 to 120° C. for the temperature rise rate of 10° C./min.

22. The anisotropic conductive film according to claim 4, wherein the exothermic peak temperature in a differential scanning calorimeter is 110 to 120° C. for the temperature rise rate of 10° C./min.
